(19) United States
(12) Patent Application Publication
(10) Pub. No.: US 2010/0244065 A1
(43) Pub. Date: Sep. 30, 2010

(54) SEMICONDUCTOR LIGHT EMITTING DEVICE GROWN ON AN ETCHABLE SUBSTRATE

(75) Inventor: Mark M. Butterworth, Santa Clara, CA (US)

Correspondence Address: PHILIPS INTELLECTUAL PROPERTY & STANDARDS, P.O. BOX 3001, BRIARCLIFF MANOR, NY, 10510, US

(73) Assignees: KONINKLIJKE PHILIPS ELECTRONICS N.V., Eindhoven (NL); PHILIPS LUMILEDS LIGHTING COMPANY, LLC, San Jose, CA (US)

(21) Appl. No.: 12/413,695

(22) Filed: Mar. 30, 2009

(51) Int. Cl. H01L 33/00; H01L 21/18

(52) U.S. Cl. 257/98; 438/29; 257/E33.067; 257/E21.085

(57) ABSTRACT

A III-nitride structure comprising a light emitting layer disposed between an n-type region and a p-type region is grown on a silicon substrate. The III-nitride structure is attached to a host, then a portion of the silicon substrate is etched away to reveal a top surface of the III-nitride structure. In some embodiments, the silicon substrate is etched to form an enclosure on the top surface of the III-nitride structure. A wavelength converting material such as phosphor may be disposed in the enclosure.

### FIELD OF INVENTION

The present invention is directed to a semiconductor light emitting device grown on a growth substrate that can be etched.

### BACKGROUND

Semiconductor light-emitting devices including light emitting diodes (LEDs), resonant cavity light emitting diodes (RCLEDs), vertical cavity laser diodes (VCSELs), and edge emitting lasers are among the most efficient light sources currently available. Materials systems currently of interest in the manufacture of high-brightness light emitting devices capable of operation across the visible spectrum include Group III-V semiconductors, particularly binary, ternary, and quaternary alloys of gallium, aluminum, indium, and nitrogen, also referred to as III-nitride materials, and binary, ternary, and quaternary alloys of gallium, aluminum, indium, and phosphorus, also referred to as III-phosphide materials. Typically, III-nitride light emitting devices are fabricated by epitaxially growing a stack of semiconductor layers of different compositions and dopant concentrations on a sapphire, silicon carbide, III-nitride, or other suitable substrate by metal-organic chemical vapor deposition (MOCVD), molecular beam epitaxy (MBE), or other epitaxial techniques. The stack often includes one or more n-type layers doped with, for example, Si, formed over the substrate, a light emitting or active region formed over the n-type layer or layers, and one or more p-type layers doped with, for example, Mg, formed over the active region. III-nitride devices formed on conductive substrates may have the p- and n-contacts formed on opposite sides of the device. Often, III-nitride devices are fabricated on insulating substrates, such as sapphire, with both contacts on the same side of the device. Such devices are mounted so light is extracted either through the contacts (known as an epitaxy-up device) or through a surface of the device opposite the contacts (known as a flip chip device).

III-nitride LEDs structures are often grown on sapphire substrates due to sapphire's high temperature stability and relative ease of production. The use of a sapphire substrate may lead to poor extraction efficiency due to the large difference in index of refraction at the interface between the semiconductor layers and the substrate. When light is incident on an interface between two materials, the difference in index of refraction determines how much light is totally internally reflected at that interface, and how much light is transmitted through it. The larger the difference in index of refraction, the more light is reflected. The refractive index of sapphire (1.8) is low compared to the refractive index of the III-nitride device layers (2.4) grown on the sapphire. Thus, a large portion of the light generated in the III-nitride device layers is reflected when it reaches the interface between the semiconductor layers and a sapphire substrate. The totally internally reflected light must scatter and make many passes through the device before it is extracted. These many passes result in significant attenuation of the light due to optical losses at contacts, free carrier absorption, and interband absorption within any of the III-nitride device layers. The use of other growth substrates with an index of refraction that more closely matches that of the III-nitride material may reduce but generally will not completely eliminate the optical losses. Similarly, due to the large difference in index of refraction between III-nitride materials and air, elimination of the growth substrate also will not eliminate the optical losses.

Phosphors are luminescent materials that can absorb an excitation energy (usually radiation energy), then emit the absorbed energy as radiation of a different energy than the initial excitation energy. State-of-the-art phosphors have quantum efficiencies near 100%, meaning nearly all photons provided as excitation energy are reemitted by the phosphor. State-of-the-art phosphors are also highly absorbent. If a light emitting device can emit light directly into such a highly efficient, highly absorbent phosphor, the phosphor may efficiently extract light from the device, reducing the optical losses described above.

Conventional III-nitride flip chip devices, where light must pass through a sapphire growth substrate before being incident on the phosphor, do not exploit these properties of phosphor. As described above, much light is trapped within the semiconductor layers due to the step in refractive index at the interface between the device layers and the substrate.

U.S. Pat. No. 7,341,878 describes devices where a phosphor is closely coupled to one of the semiconductor layers to facilitate efficient extraction of light. FIG. 1 illustrates a device described in U.S. Pat. No. 7,341,878 where grains of phosphor are deposited on a III-nitride surface of a device exposed when the growth substrate is removed. Phosphor grains 34 are deposited on a surface of n-type region 10. The phosphor grains 34 are in direct contact with n-type region 10, such that light emitted from active region 14 is directly coupled to phosphor grains 34. An optical coupling medium 32 may be provided to hold phosphor grains 34 in place. Optical coupling medium 32 is selected to have a refractive index that is, for example, higher than 1.5, and as close as possible without significantly exceeding the index of refraction of n-type region 10. For most efficient operation, no lossy media are included between n-type region 10, phosphor grains 34, and optical coupling medium 32. Phosphor grains 34 generally have a grain size between 0.1 and 20 microns, and more typically have a phosphor grain size between 1 and 8 microns.

The device illustrated in FIG. 1 may be formed by growing the device layers on a conventional growth substrate, bonding the device layers to a host substrate 38, for example through metal layers 50, then removing the growth substrate. In order to remove a sapphire growth substrate, portions of the interface between the sapphire substrate and the epitaxially grown crystal region are exposed, through the substrate, to a high fluence pulsed ultraviolet laser in a step and repeat pattern. The photon energy of the laser is above the band gap of the crystal layer adjacent to the sapphire (usually GaN), thus the pulse energy is effectively converted to thermal energy within the first 100 nm of epitaxial material adjacent to the sapphire. At sufficiently high fluence (i.e. greater than about 1.5 J/cm²) and a photon energy above the band gap of GaN and below the absorption edge of sapphire (i.e. between about 3.44 and about 6 eV), the temperature within the first 100 nm rises on a nanosecond scale to a temperature greater than 1000° C., high enough for the GaN to dissociate into gallium and nitrogen gasses, releasing the epitaxial layers from the substrate.

A contact 18 is then formed on n-type region 10. The epitaxial layers beneath contact 18, region 36 on FIG. 2, may be implanted with, for example, hydrogen to prevent light emission from the portion of the active region 14 beneath contact 18. Phosphor grains 34 are then deposited directly on the exposed surface of n-type region 10.

### SUMMARY

An object of the invention is to form a semiconductor light emitting device on a substrate that may be etched, such as silicon. In some embodiments of the invention, a III-nitride structure comprising a light emitting layer disposed between an n-type region and a p-type region is grown on a silicon substrate. The III-nitride structure is attached to a host, then a portion of the silicon substrate is etched away to reveal a top surface of the III-nitride structure.

In some embodiments, the silicon substrate is etched to form an enclosure on the top surface of the III-nitride structure. A wavelength converting material such as phosphor may be disposed in the enclosure, in contact with the III-nitride structure, which may improve light extraction from the device. In some embodiments, the remaining silicon substrate may mechanically support the III-nitride structure.

### BRIEF DESCRIPTION OF THE DRAWINGS

FIG. 1 illustrates a III-nitride device from which the growth substrate has been removed, including a phosphor layer.

FIG. 2 illustrates a III-nitride device grown on a silicon substrate.

FIG. 3 illustrates a III-nitride device flip-chip mounted on a host.

FIG. 4 illustrates the device of FIG. 3 after etching an enclosure in the silicon substrate and disposing a wavelength converting material in the enclosure.

FIG. 5 is a top view of the device of FIG. 4.

FIG. 6 is a top view of a device with multiple enclosures formed in a silicon substrate.

FIG. 7 illustrates multiple III-nitride devices on a wafer.

### DETAILED DESCRIPTION

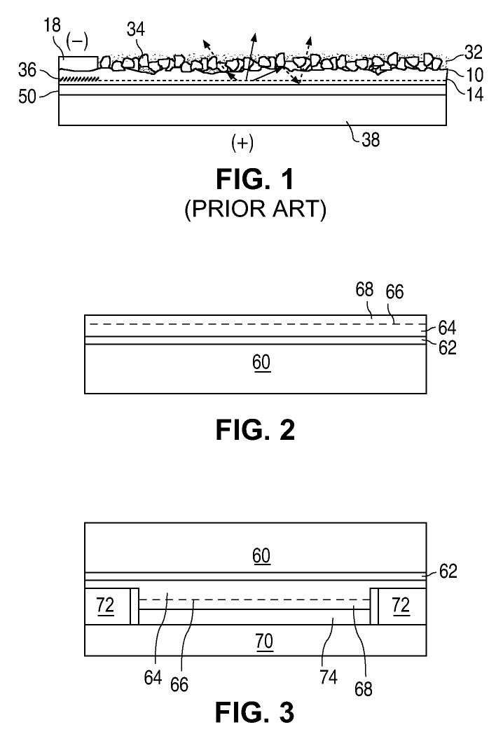

In the device illustrated in FIG. 1, the semiconductor structure is bonded to a host, then the growth substrate, usually sapphire, is removed, usually by laser lift-off. Removing the growth substrate by laser lift-off causes shock waves that can damage the semiconductor layers in the device.

In accordance with embodiments of the invention, a III-nitride light emitting device is grown on a substrate that can be etched, such as silicon. After growth, the silicon substrate may be etched to reveal a surface of the III-nitride structure and form an enclosure in which a wavelength converting material such as phosphor is disposed. A wavelength converting material disposed directly on the III-nitride material may improve the efficiency of the device.

Growth of III-nitride materials on silicon is known. Prior to the growth of GaN layers on a Si substrate, the Si substrate may be prepared, for example by bathing the Si wafer in a BOE (buffered oxide etch) etchant (10:1). The wafer may then be rinsed with deionized (DI) water to remove BOE etchant residues from the Si wafer. After removal from the DI water, any residual water may be removed with a nitrogen gas stream. The Si wafer may then be loaded into a metalorganic chemical vapor deposition (MOCVD) system growth reactor for a wafer bake procedure. The pressure used in the MOCVD reactor may be, for example, about 100 Torr and the bake gas may be, for example, hydrogen. The wafer bake process may be performed at a temperature of about 1150° C. for about 10 minutes. The wafer may then be exposed to trimethylaluminum in a hydrogen atmosphere at a pressure of about 100 Torr and a temperature of about 1150° C. for about 4-8 seconds, to form a nucleation layer.

Before growing III-nitride device layers such as a light emitting layer sandwiched between an n-type region and a p-type region, a buffer layer may be deposited first on the Si substrate. The buffer layer may at least partially compensate for the large lattice mismatch between the Si substrate and the III-nitride device layers formed after the buffer layer. Examples of suitable buffer layers include AlN, AlGaN, AlInGaN, InGaN, and SiCN. Multiple buffer layers, or a buffer layer with graded composition, may be used.

Epitaxial techniques other than MOCVD may be used, such as molecular beam epitaxy (MBE), and hydride vapor phase epitaxy (HVPE), amongst other techniques. The growth of GaN on Si substrates is described in, for example, U.S. Pat. Nos. 6,649,287, 6,818,061, and 7,014,710.

FIGS. 2, 3, and 4 illustrate how to form a device according to embodiments of the invention. In FIG. 2, a buffer layer 62, as described above, is grown over a silicon substrate 60. A III-nitride device structure, including an n-type region 64, an active or light emitting region 66 including at least one light emitting layer, and a p-type region 68, are grown over buffer layer 62.

N-type region 64 may include multiple layers of different compositions and dopant concentration including, for example, preparation layers such as buffer layers or nucleation layers, which may be n-type or not intentionally doped, release layers designed to facilitate later release of the growth substrate or thinning of the semiconductor structure after substrate removal, and n- or even p-type device layers designed for particular optical or electrical properties desirable for the light emitting region to efficiently emit light.

A light emitting or active region 66 is grown over n-type region 64. Examples of suitable light emitting regions include a single thick or thin light emitting layer, or a multiple quantum well light emitting region including multiple thin or thick quantum well light emitting layers separated by barrier layers. For example, a multiple quantum well light emitting region may include multiple light emitting layers, each with a thickness of 25 Å or less, separated by barriers, each with a thickness of 100 Å or less. In some embodiments, the thickness of each of the light emitting layers in the device is thicker than 50 Å.

A p-type region 68 is grown over light emitting region 66. Like the n-type region, the p-type region may include multiple layers of different composition, thickness, and dopant concentration, including layers that are not intentionally doped, or n-type layers.

As illustrated in FIG. 3, one or more portions of the p-type region 68 and the light emitting region 66 are etched away to reveal one or more portions of the n-type region 64. Metal n-contacts 72 are formed on the exposed portions of n-type region 64 and metal p-contact 74 is formed on the remaining portion of p-type region 68. One or both of n- and p-contacts 72 and 74 may be reflective. The device is then mounted on a host 70, for example by metal bonding layers (not shown in FIG. 3).

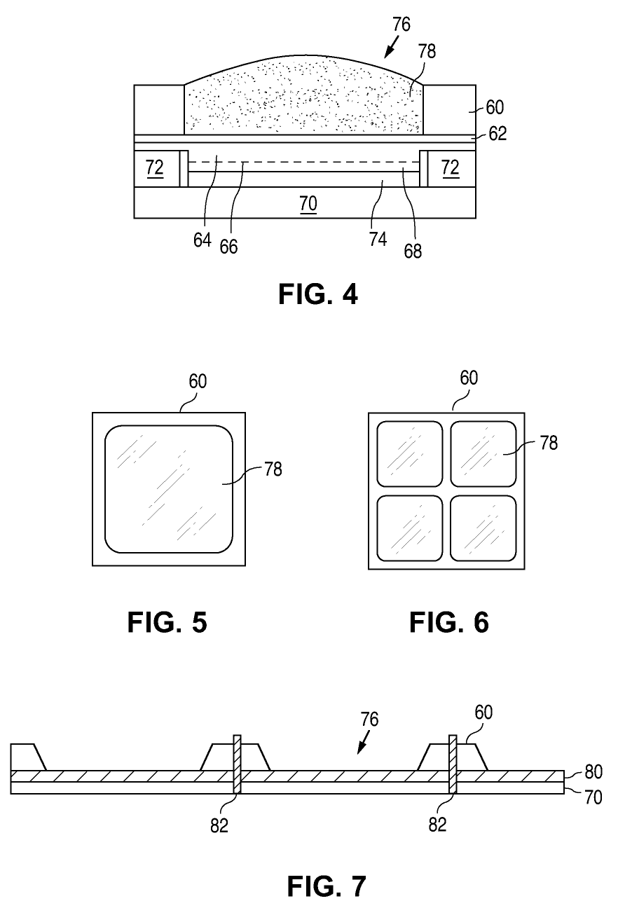

In FIG. 4, a portion 76 of the silicon substrate 60 is etched away to reveal a surface of the grown III-nitride semiconductor structure. Since silicon is absorbing to visible light, light may escape the device through the window formed by removed portion 76. Any light incident on the remaining portions of silicon substrate 60 is absorbed. The part of the silicon substrate 60 that is not etched away may provide mechanical support to the thin III-nitride semiconductor structure. In some embodiments, the III-nitride semiconductor structure may be thinned, for example by photoelectrochemical etching, after portion 76 of silicon substrate 60 is removed. Buffer layer 62 may be removed or remain part of the device, as illustrated in FIG. 4.

A wavelength converting material layer 78 may be disposed in the opening formed by removing portion 76 of silicon substrate 60. Wavelength converting material layer 78 may be, for example, a phosphor. Phosphor may be formed into a ceramic, deposited by electrophoresis, or mixed in powder form with a binding material such as high index of refraction silicone. Any suitable phosphor or phosphors may be used, to create light of a desired color. In some embodiments, blue light emitted by the light emitting region 66 mixes with light emitted from a yellow-emitting phosphor to make white light. In some embodiments, blue light emitted by the light emitting region 66 mixes with light emitted from green- and red-emitting phosphors to make white light. In some embodiments, UV light emitted by the light emitting region 66 is absorbed by blue- and yellow-emitting phosphors, or blue-, green-, and red-emitting phosphors, such that the resulting light is white. Other phosphors may be added to achieve a desired color point.

Since the phosphor is disposed directly on the III-nitride structure, the efficiency of the device may be improved over a device with a sapphire substrate between the III-nitride structure and the phosphor. In addition, since laser lift-off of the growth substrate is avoided, damage caused by laser lift-off is avoided.

In some embodiments, structures known in the art such as lenses of dichroic filters may be disposed over the III-nitride structure.

FIG. 5 is a top view of the device illustrated in FIG. 4. The remaining part of silicon substrate 60 surrounds wavelength converting material layer 78. Light can escape the device through wavelength converting material 78, but is absorbed by silicon substrate 60. In some embodiments, the sides of the remaining part of silicon substrate 60 that face wavelength converting material 78 are coated with a reflective material such as a reflective metal or a dielectric stack. Silicon substrate 60 provides mechanical support to the thin III-nitride layers. In some embodiments, the remaining part of silicon substrate 60 on the edge of the device is between 50 and 100 microns wide. The total area of the device may be, for example, at least 1 mm square. In some embodiments, if more support is needed, multiple, small openings are etched in silicon substrate 60, instead of a single large opening, as illustrated in FIG. 6. In some embodiments, the portion of silicon substrate 60 on the edge of the device in FIG. 6 is between 50 and 100 microns wide. The ribs of silicon substrate 60 in the middle section of the device may be between 50 and 100 microns wide, or narrower in some embodiments. A device with multiple small openings is illustrated in FIG. 6. Though four openings for a single device are illustrated, more or fewer may be used. A wavelength converting material may be disposed in one or more of the multiple openings illustrated in FIG. 6. In some embodiments, wavelength converting materials that emit different colors may be disposed in different openings. In some embodiments, some openings are not filled with a wavelength converting material.

In the device illustrated in FIG. 4, both the n- and p-contacts are formed on the bottom surface of the III-nitride layers. In some embodiments of the invention, a reflective p-contact is formed on the bottom surface of the III-nitride layers, and an n-contact is electrically connected to the top surface of the III-nitride layers. A top n-contact may be directly connected to the top surface of the III-nitride layers, or may be connected to a portion of the silicon substrate 60 that is made conductive.

FIG. 7 illustrates multiple III-nitride devices grown on a single silicon wafer. The III-nitride devices 80, which may be the devices illustrated in FIGS. 3 and 4, are bonded to a host 70, as described above. The silicon substrate 60 is then etched to form at least one opening 76 in the silicon substrate 60 for each device. The wafer may be diced into individual devices by sawing 82 through the silicon substrate 60 between two devices.

A silicon growth substrate may be easily etched without damaging the III-nitride device grown on the substrate. Laser melting, which may damage the III-nitride device, is not required to remove the substrate. After a portion of the silicon substrate is etched away, a phosphor may be positioned directly on the III-nitride structure, which may improve the extraction efficiency of the device over a device that emits light into air or a sapphire substrate.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

What is being claimed is:

1. A device comprising:
a III-nitride structure comprising a light emitting layer disposed between an n-type region and a p-type region;
a reflective electrical contact disposed on a bottom surface of the III-nitride structure; and
a silicon structure in direct contact with a portion of a top surface of the III-nitride structure.

2. The device of claim 1 wherein the silicon structure forms an enclosure on the top surface of the III-nitride structure, the device further comprising a wavelength converting material disposed in the enclosure.

3. The device of claim 2 wherein the wavelength converting material comprises a ceramic phosphor.

4. The device of claim 2 wherein the wavelength converting material comprises a powder phosphor and a binding material.

5. The device of claim 1 wherein the silicon structure is disposed on an edge of the top surface of the III-nitride structure.

6. The device of claim 1 wherein the silicon structure forms a grid of enclosures on the top surface of the III-nitride structure.

7. A method comprising:
growing on a silicon substrate a III-nitride structure comprising a light emitting layer disposed between an n-type region and a p-type region;
forming a reflective contact on a bottom surface of the III-nitride structure;
attaching the bottom surface of the III-nitride structure to a host;
etching away a portion of the silicon substrate to reveal a top surface of the III-nitride structure.

8. The method of claim 7 wherein etching away a portion of the silicon substrate comprises:
etching away a portion of the silicon substrate overlying a center portion of the III-nitride structure; and
leaving a portion of the silicon substrate overlying an edge of the III-nitride structure.

9. The method of claim 7 wherein etching away a portion of the silicon substrate comprises forming an enclosure on a top surface of the III-nitride structure, wherein the enclosure is surrounded by silicon substrate remaining after etching.

10. The method of claim 9 further comprising disposing a wavelength converting material in the enclosure.

11. The method of claim 10 wherein the wavelength converting material comprises a powder phosphor and a binding material.

12. The method of claim 7 wherein etching away a portion of the silicon substrate comprises forming multiple enclosures on a top surface of the III-nitride structure, wherein each enclosure is surrounded by silicon substrate remaining after etching.

13. The method of claim 12 further comprising disposing a wavelength converting material in at least one of the multiple enclosures.

14. The method of claim 7 further comprising separating two light emitting diodes by separating the III-nitride structure in a region underlying a portion of the silicon substrate remaining after etching.
